(19) United States
(12) Patent Application Publication
(10) Pub. No.: US 2008/0203497 A1
(43) Pub. Date: Aug. 28, 2008

(54) Semiconductor Devices Including Assymetric Source and Drain Regions Having a Same Width and Related Methods

(75) Inventors: Young-Chan Lee, Gyeonggi-do (KR); Seung-Han Yoo, Gyeonggi-do (KR); Dae-Lim Kang, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/032,233

(22) Filed: Feb. 15, 2008

(30) Foreign Application Priority Data
Feb. 23, 2007 (KR) 2007-18200

(51) Int. Cl. H01L 29/78; H01L 21/336

(52) U.S. Cl. 257/409; 438/286; 257/E29.255; 257/E21.409

(57) ABSTRACT

A semiconductor device may include an active region of a semiconductor substrate and first and second impurity regions in the active region. The active region may have a first conductivity type, the first and second impurity regions may have a second conductivity type opposite the first conductivity type, and the first and second impurity regions are spaced apart to define a channel region therebetween. A first source/drain region may be provided in the first impurity region, a second source/drain region may be provide in the second impurity region, the first and second source/drain regions may have the second conductivity type, and impurity concentrations of the first and second source/drain regions may be greater than impurity concentrations of the first and second impurity regions. Moreover, the first and second source/drain regions may have a same width in a direction perpendicular with respect to a direction between the first and second source/drain regions, and a distance between the first source/drain region and the channel region may be less than a distance between the second source/drain region and the channel region. In addition, a control gate may be provided on the channel region. Related methods are also discussed.

### RELATED APPLICATIONS

This application claims the benefit of priority under 35 USC §119 to Korean Patent Application No. 2007-18200, filed on Feb. 23, 2007 in the Korean Intellectual Property Office (KIPO), the disclosure of which is by incorporated herein by reference in their entirety.

### FIELD OF THE INVENTION

The present invention relates to electronics, and more particularly, to semiconductor transistor devices and related methods.

### BACKGROUND

High voltage transistors having modified lightly doped drain (MLDD) structures or field lightly doped drain (FLDD) structures have been used. For example, when a voltage less than about 30 V is applied to a high voltage transistor, the high voltage transistor may have a MLDD structure, and when a voltage more than about 45 V is applied to a high voltage transistor, the high voltage transistor may have an FLDD structure. When a voltage more than about 45 V is applied to an asymmetrical transistor, a source resistance may be relatively low compared to that of a symmetrical transistor, and a current flowing through a channel region may concentrate at an edge portion of a drain region due to a size difference between a source region and the drain region, so that a breakdown voltage may be significantly reduced.

FIG. 1 is a top view illustrating a conventional asymmetrical transistor, and FIGS. 2 and 3 are graphs illustrating breakdown voltages of conventional symmetrical and asymmetrical transistors. Particularly, FIG. 2 is a graph illustrating breakdown voltages of conventional symmetrical and asymmetrical transistors having a width of about 50 nm, and FIG. 3 is graphs illustrating breakdown voltages of the conventional symmetrical and asymmetrical transistors having a width of about 7 nm.

Referring to FIG. 1, an asymmetrical transistor 10 includes a gate structure 20, a source region 30 and a drain region 40. When a voltage corresponding to a breakdown voltage is applied to the gate structure 20 and a high voltage is applied to the source and drain regions 30 and 40, current flows through a channel region between the source and drain regions 30 and 40.

The source region 30 is larger than the drain region 40, and the current may thus concentrates at an edge portion A of the drain region 40. Accordingly, when a maximum voltage is applied to the gate structure 20 and the drain region 40, an on-breakdown voltage may be undesirably reduced.

In FIGS. 2 and 3, breakdown voltages of conventional symmetrical and asymmetrical transistors are illustrated.

Referring to FIG. 2, a dotted line indicates the breakdown voltage of the asymmetrical transistor, and a solid line indicates the breakdown voltage of the symmetrical transistor when the transistors have a width of about 50 nm. The asymmetrical transistor has breakdown voltage characteristics that are worse than those of the symmetrical transistor.

Referring to FIG. 3, a dotted line indicates the breakdown voltage of the asymmetrical transistor, and a solid line indicates the breakdown voltage of the symmetric transistor when the transistors have a width of about 7 nm. The asymmetrical transistor has breakdown voltage characteristics that are worse than those of the symmetrical transistor.

The breakdown voltage of the symmetrical transistor is very little affected by the width of the transistor, while, the breakdown voltage of the asymmetrical transistor is seriously affected by the width of the transistor. As semiconductor devices have become more highly integrated, widths of transistors have been reduced, and thus breakdown voltage characteristics of transistors have become worse. Further, a difference ratio of the width between the source region 30 and the drain region 40 may increase as the width of the transistor is reduced, and current concentrations may significantly increase at edge portions of the drain region 40, and breakdown voltage characteristics may be further diminished.

### SUMMARY

According to some embodiments of the present invention, the semiconductor device may include an active region of a semiconductor substrate and first and second impurity regions in the active region. The active region may have a first conductivity type, the first and second impurity regions may have a second conductivity type opposite the first conductivity type, and the first and second impurity regions are spaced apart to define a channel region therebetween. A first source/drain region may be provided in the first impurity region, a second source/drain region may be provide in the second impurity region, the first and second source/drain regions may have the second conductivity type, and impurity concentrations of the first and second source/drain regions may be greater than impurity concentrations of the first and second impurity regions. Moreover, the first and second source/drain region have about a same width in a direction perpendicular with respect to a direction between the first and second source/drain regions.

An insulating field layer on a surface of the semiconductor substrate may be provided with portions the insulating layer extending on portions of the first and second impurity regions. A first portion of the insulating field layer may be on the second impurity region between the second source/drain region and the channel region, and portions of the first impurity region between the first source/drain region and the channel region may be free of the insulating field layer. Moreover, a second portion of the insulating field layer may be on the second impurity region so that the second source/drain region is between the first and second portions of the insulating field layer, and a third portion of the insulating field layer may be on the first impurity region so that the first source/drain region is between the channel region and the third portion of the insulating field layer. The control gate may include a gate insulation layer on the channel region and a gate conductive layer on the gate insulation layer, and portions of the gate conductive layer may extend onto the first portion of the insulating field layer. A thickness of the insulating field layer may be greater than a thickness of the gate insulation layer.

Current flow between the first and second source/drain regions may be through the channel region in a direction perpendicular with respect to a direction of the widths of the first and second source/drain regions. The first and second source/drain regions spaced from edge portions of the first and second impurity regions by a distance of at least about 2.5 Angstroms. The first and second source/drain regions may be spaced from edge portions of the first and second impurity regions by a distance of at least about 2.5 Angstroms in the direction perpendicular with respect to the direction between the first and second source/drain regions.

The control gate a gate insulation layer on the channel region and a gate conductive layer on the gate insulation layer, and portions of the gate insulation layer may extend beyond the gate conductive layer onto portions of the first impurity regions so that portions of the gate insulation layer are free of the gate conductive layer. The control gate may include a gate insulation layer on the channel region and a gate conductive layer on the gate insulation layer, and a width of the gate insulation layer in the direction perpendicular with respect to the direction between the first and second source/drain regions may be greater than a width of the gate conductive layer in the same direction. The first source/drain region may be a source, and the second source/drain region may be a drain. Moreover, a distance between the first source/drain region and the channel region may be less than a distance between the second source/drain region and the channel region. In addition, a control gate may be provided on the channel region.

According to other embodiments of the present invention, a method of forming a semiconductor device may include forming first and second impurity regions in an active region of a semiconductor substrate with the active region having a first conductivity type, the first and second impurity regions having a second conductivity type opposite the first conductivity type, and with the first and second impurity regions being spaced apart to define a channel region therebetween. A control gate may be formed on the channel region. A first source/drain region may be formed in the first impurity region. The first source/drain region may have the second conductivity type, and an impurity concentration of the first source/drain region may be greater than an impurity concentration of the first impurity region. A second source/drain region may be formed in the second impurity region. The second source/drain region may have the second conductivity type, an impurity concentration of the first source/drain region may be greater than an impurity concentration of the second impurity region, and the first and second source/drain region have about a same width in a direction perpendicular with respect to a direction between the first and second source/drain regions.

Before forming the control gate, an insulating field layer may be formed on a surface of the semiconductor substrate, and portions of the insulating layer may extend on portions of the first and second impurity regions. Forming the insulating field layer may include forming the insulating field layer using local oxidation of silicon (LOCOS).

A first portion of the insulating field layer may be on the second impurity region between the second source/drain region and the channel region. Portions of the first impurity region between the first source/drain region and the channel region may be free of the insulating field layer. A second portion of the insulating field layer may be on the second impurity region so that the second source/drain region is between the first and second portions of the insulating field layer, and a third portion of the insulating field layer may be on the first impurity region so that the first source/drain region is between the channel region and the third portion of the insulating field layer. Forming the first and second source/drain regions may include implanting impurities for the first and second source/drain regions using the first, second, and third portions of the insulating field layer and the control gate as an implant mask. Moreover, forming the control gate may include forming a gate insulation layer on the channel region, and forming a gate conductive layer on the gate insulation layer wherein portions of the gate conductive layer extend onto the first portion of the insulating field layer. A thickness of the insulating field layer may be greater than a thickness of the gate insulation layer.

Current flow between the first and second source/drain regions may be through the channel region in a direction perpendicular with respect to a direction of the widths of the first and second source/drain regions. The first and second source/drain regions may be spaced from edge portions of the first and second impurity regions by a distance of at least about 2.5 Angstroms. The first and second source/drain regions may be spaced from edge portions of the first and second impurity regions by a distance of at least about 2.5 Angstroms in the direction perpendicular with respect to the direction between the first and second source/drain regions.

Forming the control gate forming a gate insulation layer on the channel region, and forming a gate conductive layer on the gate insulation layer wherein portions of the gate insulation layer extend beyond the gate conductive layer onto portions of the first impurity regions so that portions of the gate insulation layer are free of the gate conductive layer. Forming the control gate may include forming a gate insulation layer on the channel region, and forming a gate conductive layer on the gate insulation layer wherein a width of the gate insulation layer in the direction perpendicular with respect to the direction between the first and second source/drain regions is greater than a width of the gate conductive layer in the same direction. The first source/drain region a source and the second source/drain region may be a drain. Moreover, a distance between the first source/drain region and the channel region may be less than a distance between the second source/drain region and the channel region.

Some embodiments of the present invention may provide semiconductor devices with reduced current concentrations at edge portions of a drain region thereof.

Some embodiments of the present invention may provide a method of manufacturing semiconductor devices at edge portions of a drain region thereof.

In accordance with some embodiments of the present invention, a semiconductor device may include an active region, a field region, a source region, a drain region and a gate structure. The active region may be formed in a semiconductor substrate. The active region may include a first impurity region, a second impurity region, and a channel region formed between the first impurity region and the second impurity region. The field region may be formed on the semiconductor substrate and may partially overlap the first and second impurity regions. The source region may be formed in the first impurity region and may be adjacent to the channel region. The source region may have a first width. The drain region may be formed in the second impurity region and may be spaced apart from the channel region. The drain region may have a second width substantially the same as the first width. The gate structure may be formed on the channel region.

In some embodiments, the field region may have a given height from an upper face of the semiconductor substrate. In some embodiments, the source region may be formed at a portion of the first impurity region between the field region and the channel region, and the drain region may be spaced apart from the channel region across the field region that is adjacent to the channel region. In some embodiments, a current may flow through the channel region in a first direction, and the first and second widths may be measured in a second direction substantially perpendicular to the first direction.

In some embodiments, the source and drain regions may be inwardly spaced apart from an edge portion of the impurity region by about 2.5 Å (Angstroms). In some embodiments, the source and drain regions may be doped with first impurities having a concentration higher than a concentration of second impurities doped into the first and second impurity regions. In some embodiments, the gate structure may include a gate insulation layer pattern and a gate conductive layer pattern sequentially stacked on the channel region. The gate insulation layer pattern has a width greater than that of the gate conductive layer pattern.

In other embodiments, the gate structure may include a gate insulation layer pattern formed on the channel region, and a gate conductive layer pattern formed on the gate insulation layer pattern and the field region adjacent to the channel region. Here, a portion of the gate insulation layer pattern may extend toward the source region.

In accordance with some embodiments of the present invention, a method of manufacturing a semiconductor device may include forming an active region including a first impurity region, a second impurity region, and a channel region between the first and second impurity regions. A field region may partially overlap the first impurity region and the second impurity region. A gate structure may be formed on the channel region, and a source region may be formed adjacent to the channel region in the first impurity region. The source region may have a first width. The drain region may be spaced apart from the channel region in the second impurity region. The drain region may have a second width substantially the same as the first width.

In some embodiments, the field region may be formed using a local oxidation of silicon (LOCOS) process. In some embodiments, to form the gate structure, a gate insulation layer pattern may be formed on the channel region, and a gate conductive layer pattern may then be formed on the gate insulation layer pattern. The gate insulation layer pattern may be formed to have a width greater than that of the gate conductive layer pattern.

In some embodiments, the source region may be formed at a portion of the first impurity region between the channel region and the field region, and the drain region may be formed to be spaced apart from the channel region by the field region adjacent to the channel region. In some embodiments, a current may flow through the channel region in a first direction, and the first and second widths may be measured in a second direction substantially perpendicular to the first direction. In some embodiments, the source and drain regions may be inwardly spaced apart from an edge portion of the impurity region by about 2.5 Å (Angstroms). According to embodiments of the present invention, the source region may have the first width substantially same as the second width of the drain width, and thus current concentration may be reduced at an edge portion of the drain region.

### BRIEF DESCRIPTION OF THE DRAWINGS

FIG. 1 is a top view illustrating a conventional asymmetrical transistor.

FIGS. 2 and 3 are graphs illustrating breakdown voltages of conventional symmetrical and asymmetrical transistors.

FIG. 4 is a top view illustrating a semiconductor device according to some embodiments of the present invention.

FIG. 5 is a cross-sectional view of the semiconductor device of FIG. 4 taken along section line I-I′ of FIG. 4.

FIGS. 6 to 8 are cross-sectional views illustrating operations of manufacturing a semiconductor device according to some embodiments of the present invention.

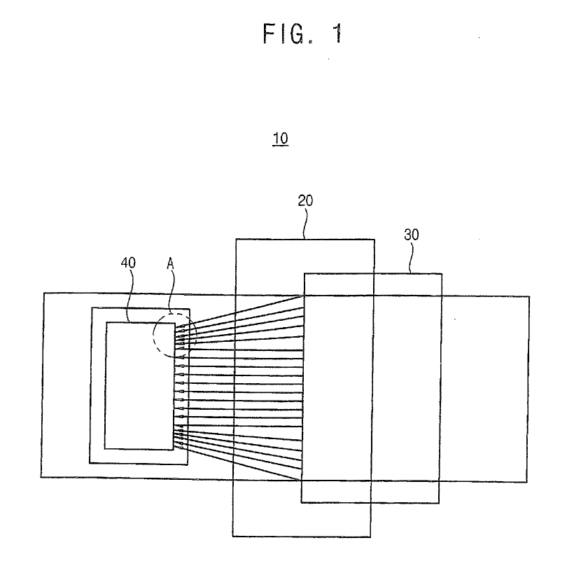

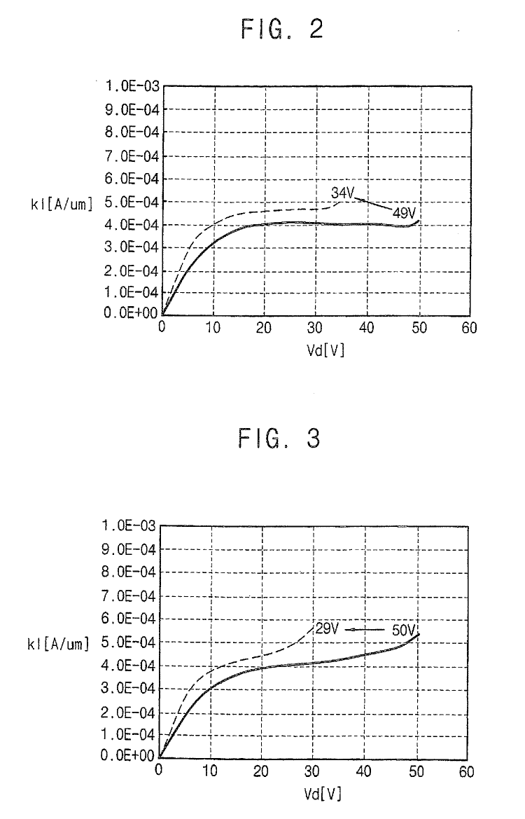

### DETAILED DESCRIPTION

The present invention is described more fully hereinafter with reference to the accompanying drawings, in which examples of embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and thickness and relative sizes and thickness of layers and regions may be exaggerated for clarity.

It will be understood that when an element or layer is referred to as being “on” or “connected to” another element or layer, it can be directly on, connected or coupled to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Examples of embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

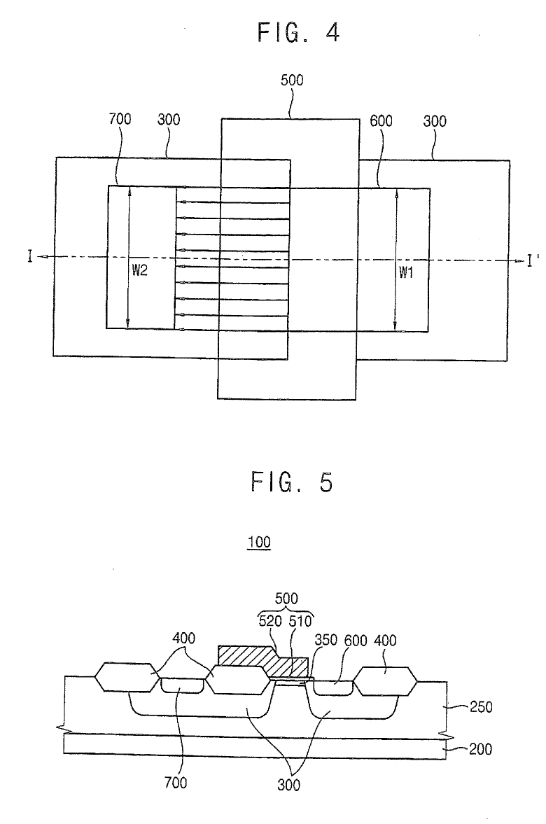

FIG. 4 is a top view illustrating a semiconductor device according to some embodiments of the present invention, and FIG. 5 is a cross-sectional view of the semiconductor device of FIG. 4 taken along section line I-I′ of FIG. 4.

Referring to FIGS. 4 and 5, a semiconductor device 100 may include a semiconductor substrate 200, impurity regions 300, a field region(s) 400, a gate structure 500, a source region 600 and a drain region 700. For example, the semiconductor substrate 200 may include a single crystalline silicon substrate, a single crystalline germanium substrate, a single crystalline silicon-germanium substrate, etc.

A well region 250 may be formed at a first upper portion of the substrate 200. In some embodiments of the present invention, first impurities having a concentration may be implanted into the first upper portion of the substrate 200 to form the well region 250. The first impurities may be implanted into the first upper portion of the substrate 200 using ion implantation. A conductivity type of the first impurities included in the well region 250 may be changed in accordance with a type of a transistor formed on the well region 250. When an n-type metal-oxide-semiconductor (NMOS) transistor is formed on the substrate 200, p-type impurities may be implanted into the substrate 200. When a p-type metal-oxide-semiconductor (PMOS) transistor is formed on the substrate 200, n-type impurities may be implanted into the substrate 200. For example, p-type impurities may include boron (B), indium (In), etc., and n-type impurities may include phosphorus (P), arsenic (As), etc.

Second impurities may be implanted into a second upper portion of the substrate 200 to form the impurity regions 300 having a given depth from an upper face of the substrate 200. The impurity regions 300 may be formed within the well region 250. For example, the second impurities may include an element in Group IIIA or an element in Group VA. In some example embodiments of the present invention, a plurality of impurity regions 300 may be formed to be spaced apart from each other. A channel region 350 through which currents flow may be provided between the impurity regions 300. That is, the impurity regions 300 may define the channel region 350. The channel region 350 between the impurity regions 300 may be under the gate structure 500.

The impurity region 300 may surround respective source and drain regions 600 and 700. More particularly, a high voltage may be applied to the source and drain regions 600 and 700 in the semiconductor device 100. A punch-through voltage between the source and drain regions 600 and 700 and the substrate 200 may be higher than a high voltage applied to the source and drain regions 600 and 700. Additionally, a breakdown voltage between the source and drain regions 600 and 700 and substrate 200 or the well region 250 may be higher than the high voltage applied to the source and drain regions 600 and 700. Thus, the impurity regions 300 may be formed to surround the source and drain regions 600 and 700.

Some embodiments of the present invention, the field region(s) 400 may be formed by a local oxidation of silicon (LOCOS) process. The field region(s) 400 may be formed to have a given height from the upper face of the substrate 200 using the LOCOS process. Alternatively, the field region(s) 400 may be formed using a self-aligned shallow trench isolation (SA-STI) process in which the gate structure 500 and an active region may be simultaneously formed.

According to some embodiments of the present invention, the field region(s) 400 may be formed in the impurity region 300. Alternatively, the field region(s) 400 may be spaced apart from the impurity region 300. A position of the field region(s) 400 may be changed in accordance with a position of a mask regardless of a position of the impurity region 300. In some embodiments of the present invention, a portion of the field region(s) 400 may overlap with the impurity region 300. Thus, an active region may be defined as a region excluding the field region(s) 400.

The gate structure 500 may include a gate insulation layer pattern 510 and a gate conductive layer pattern 520. The gate insulation layer pattern 510 may be formed on a portion of the substrate 200 exposed between the impurity regions 300. The gate insulation layer pattern 510 may be formed on the channel region 350. Additionally, the gate insulation layer pattern 510 may be formed extending on an edge portion of the impurity region 300 adjacent to the source region 600. In some embodiments of the present invention, the gate insulation layer pattern 510 may have a width greater than that of the gate conductive layer pattern 520. Thus, the gate conductive layer pattern 520 may be relatively unaffected by a high voltage when the high voltage is applied to the source region 600.

The gate conductive layer pattern 520 may be formed on the gate insulation layer pattern 510 and on a portion of the field region 400 adjacent to the gate insulation layer pattern 510. The gate structure 500 may further include a spacer (not shown) formed on a sidewall of the gate conductive layer pattern 520. The spacer may be formed using an anisotropic etching process on a silicon nitride layer after forming the silicon nitride layer on the gate conductive layer pattern 520.

Third impurities may be implanted into a first portion of impurity region 300 adjacent to gate insulation layer pattern 510 to form source region 600. The third impurities used to form source region 600 may have a concentration higher than that of the second impurities used to form impurity regions 300. In some embodiments, the second and third impurities may include an element that belongs to the same group in the periodic table. For example, the third impurities may include an element in Group IIIA or an element in Group VA corresponding to that of the second impurities.

Fourth impurities may be implanted into a second portion of the impurity region 300 spaced apart from the gate structure 500 to form the drain region 700. In some embodiments, the fourth impurities implanted into the drain region 700 may have a conductivity type substantially the same as that of the third impurities implanted into the source region 600. Additionally, the fourth impurities may be substantially the same as the third impurities with respect to element and/or concentration.

The source and drain regions 600 and 700 may be inwardly spaced apart from edge portions of impurity region 300. For example, the source and drain regions 600 and 700 may be inwardly spaced from edge portions of impurity regions 300 by about 2.5 Å (Angstroms). As mentioned above, the source and drain regions 600 and 700 may be doped more highly than the impurity regions 300, and a high voltage may be applied to the source and drain regions 600 and 700. Thus, current through the channel region 350 may be reduced even though high voltage is applied to the source and drain regions 600 and 700 because the source and drain regions 600 and 700 are surrounded by the impurity regions 300.

The source region 600 may have a first width W1, and the drain region 700 may have a second width W2. In some embodiments, the first width W1 may be substantially the same as the second width W2. Here, the first and second widths W1 and W2 may be measured in a specific direction. For example, the specific direction may be a direction in which each of the source and drain regions 600 and 700 extends. Thus, the channel region 350 may have a width substantially the same as that of the source region 600 and/or the drain region 700. Thus, when the high voltage is applied to the source and drain regions 600 and 700, current flowing through the channel region 350 between the source and drain regions 600 and 700 may be relatively uniform throughout the width of the drain region 600. As a result, a phenomenon that currents concentrate at an edge portion of the drain region 700 may be reduced and/or prevented.

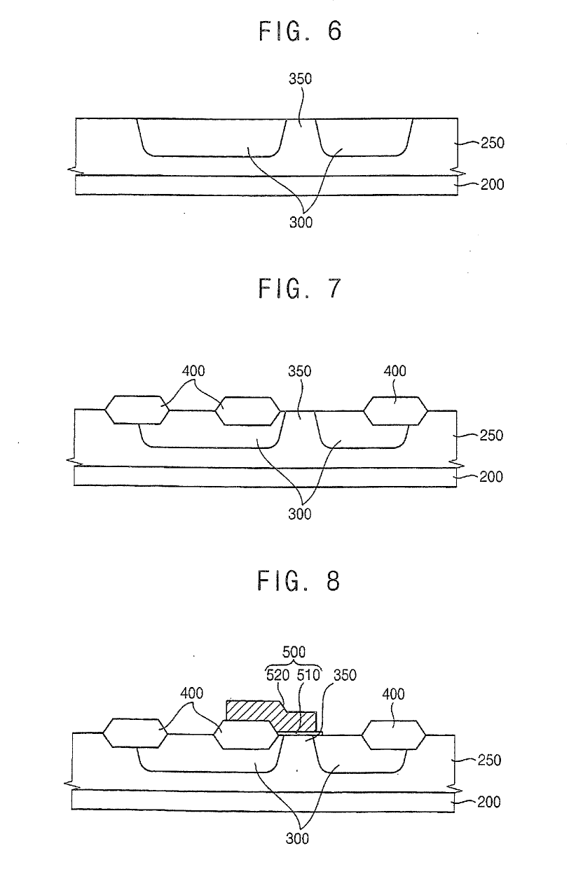

FIGS. 6 to 8 are cross-sectional views illustrating operations of manufacturing a semiconductor device according to some embodiments of the present invention.

Referring to FIG. 6, a well region 250 may be formed at a first upper portion of the semiconductor substrate 200. According to some embodiments, first impurities may be implanted into the first upper portion of the substrate 200 at a relatively low concentration using an ion implantation process to form the well region 250. A conductivity type of the first impurities included in the well region 250 may be determined/provided in accordance with a type of a transistor formed on the well region 250. For example, when an NMOS transistor is formed on the substrate 200, p-type impurities may be implanted into the substrate 200, and when a PMOS transistor is formed on the substrate 200, n-type impurities may be implanted into the substrate 200.

Second impurities may be implanted into a second upper portion of the substrate 200 to form impurity regions 300. The second impurities may have a conductivity type different from that of the first impurities of the well region 250. More particularly, when the first impurities having a p-type conductivity are implanted into the first upper portion of the substrate 200 to form the well region 250, the second impurities having an n-type conductivity may be implanted into the second upper portion of the substrate 200 to form the impurity regions 300. Alternatively, when the first impurities having an n-type conductivity are implanted into the first upper portion of the substrate 200 to form the well region 250, the second impurities having a p-type conductivity may be implanted into the second upper portion of the substrate 200 to form the impurity regions 300.

The impurity regions 300 may be formed using an ion implantation process. More particularly, a photoresist pattern (not shown) exposing the second upper portion of the substrate 200 may be formed on the substrate 200. The second impurities may be implanted into the second upper portion of the substrate 200 to form the impurity regions 300. The photoresist pattern may be removed from the substrate 200 after forming the impurity region 300. Methods of forming the impurity region 300 may be varied, and are not confined to the above method.

In some embodiments, a plurality of impurity regions 300 may be formed spaced apart from each other. Accordingly, a channel region 350 may be provided between the impurity regions 300. That is, the impurity regions 300 may define the channel region 350.

Referring to FIG. 7, a field region(s) 400 may be formed on the impurity regions 300. Alternatively, the field region(s) 400 may be formed so that a portion thereof may be offset from the impurity regions 300. In some embodiments, a plurality of the field regions 400 may be formed. The field region(s) 400 may define an active region in the substrate 200. Further, a gate structure 500, a source region 600 and a drain region 700 (see FIG. 8) may be formed on/in the active region.

For example, the field region(s) 400 may be formed using a LOCOS process. In a LOCOS process, thermal oxidation may be selectively performed on the substrate 200 (such as a single crystalline silicon substrate) to thereby form the field region(s) 400. Accordingly, the field region(s) 400 may be formed to have a given height from the upper face of the substrate 200. Alternatively, the field region 400 may be formed using a SA-STI process.

Referring to FIG. 8, the gate structure 500 may be formed on the substrate 200. More particularly, the gate structure 500 may be formed on one of the field regions 400 and on a portion of the substrate 200 exposed between the impurity regions 300. The portion of the substrate 200 exposed between the impurity regions 300 may define the channel region 350. That is, the gate structure 500 may be formed on the channel region 350 and one of the field regions 400 adjacent to the channel region 350. In this case, the gate structure 500 may have a stepped portion because of a height difference between the field region 400 and the channel region 350 on which the gate structure 500 is formed.

In some embodiments, the gate structure 500 may be formed to include a gate insulation layer pattern 510 and a gate conductive layer pattern 520. More particularly, the gate insulation layer pattern 510 may be formed on the channel region 350 as follows. A gate insulation layer may be formed on the channel region 350, and the gate insulation layer may be partially etched using a photolithography process to form the gate insulation layer pattern 510.

In some embodiments, the gate insulation layer pattern 510 may be formed on edge portions of the impurity region 300 adjacent to the channel region 350. The gate insulation layer pattern 510 may be formed to have a width greater than that of the gate conductive layer pattern 520. Thus, the gate conductive layer pattern 520 may not be significantly affected by a high voltage when the high voltage is applied to the source region 600.

The gate conductive layer pattern 520 may be formed on the gate insulation layer pattern 510 and the field region 400 adjacent to the gate insulation layer pattern 510. For example, the gate conductive layer pattern 520 may be formed using polysilicon, a metal, a metal nitride, etc.

A spacer (not shown) may be formed on a sidewall of the gate conductive layer pattern 520. The spacer may be formed using an anisotropic etching process on a silicon nitride layer, after forming the silicon nitride layer on the gate conductive layer pattern 520. The spacer may reduce and/or prevent electrical contact between the gate structure 500 and a pad (not shown) and/or between the gate structure 500 and a conductive contact (not shown) adjacent to the gate structure 500. Thus, the spacer may be formed using silicon nitride, silicon oxynitride, etc.

Referring again to FIG. 5, third impurities may be implanted into a first portion of the impurity region 300 adjacent to the gate insulation layer pattern 510 to form a source region 600. Additionally, fourth impurities may be implanted into a second portion of the impurity region 300 spaced apart from the gate structure 500 to form a drain region 700. The third and fourth impurities may be implanted to provide a concentration higher than that of the second impurities. In some embodiments, the third and fourth impurities may include an element that belongs to the same group in the periodic table as that of the second impurities.

In some embodiments, the source and drain regions 600 and 700 may be formed using an ion implantation process with the gate structure 500 and the field region(s) 400 acting as an ion implantation mask. Thus, source and drain regions 600 and 700 may be formed at first and second portions of the impurity region(s) 300 exposed by the ion implantation mask, respectively. The source and drain regions 600 and 700 doped with the third and fourth impurities at relatively high concentrations may be formed to be surrounded by impurity region(s) 300 doped with the second impurities having a relatively low concentrations. In some embodiment, source and drain regions 600 and 700 may be inwardly spaced from edge portions of impurity region(s) 300 by about 2.5 Å (Angstroms). Thus, when a high voltage is applied to source and drain regions 600 and 700, current through the channel region 350 may be reduced and/or prevented even though the high voltage does not reach a breakdown voltage, because the source and drain regions 600 and 700 are surrounded by the impurity region(s) 300. Distance between source and drain regions 600 and 700 and edge portions of impurity region(s) 300 may be changed in accordance with the voltage applied to the source and drain regions 600 and 700.

When source and drain regions 600 and 700 are formed in the impurity region(s) 300, the source region 600 may be electrically connected to the drain region 700 through the impurity region(s) 300 surrounding the source and drain regions 600 and 700. Thus, source and drain regions 600 and 700 may be insulated from each other as discussed with respect to the following embodiments. In some embodiments, when a plurality of impurity regions 300 is formed in the substrate 200, one of the impurity regions 300 may be formed to be spaced apart from another of the impurity regions 300. In other embodiments, an insulation region (not shown) may be formed between one of the impurity regions 300 surrounding the source region 600 and another of the impurity regions 300 surrounding the drain region 700 using an additional insulation process.

As shown in FIG. 4, source region 600 may have a first width W1 substantially the same as a second width W2 of the drain region 700. Here, first and second widths W1 and W2 may be measured in a specific direction. For example, the specific direction may be a direction in which each of the source and drain regions 600 and 700 extends. Stated in other words, widths W1 and W2 may be measured in a direction perpendicular with respect to a direction between source and drain regions 600 and 700. Thus, the channel region 350 may have a width substantially the same as widths W1 and W2 of source region 600 or drain region 700. Thus, when the high voltage is applied to the source and drain regions 600 and 700, current through the channel region 350 between source and drain regions 600 and 700 may be relatively uniform throughout a width of drain region 600. As a result, a phenomenon of currents concentration at edge portions of drain region 700 may be reduced and/or prevented.

Although NMOS transistors have been discussed above by way of example, embodiments of the present invention may be provided as PMOS transistors. When manufacturing a PMOS transistor according to embodiments of the present invention, processes are substantially the same as discussed above when manufacturing NMOS transistors, except that impurities having an n-type conductivity are implanted into the well region and impurities having a p-type conductivity are implanted into the impurity region and the source and drain regions.

According to embodiments of the present invention, in a semiconductor device including an asymmetrical transistor, source and drain regions may have substantially the same width. Accordingly, a channel region between the source and drain regions may also have a width substantially the same as widths of the source and drain regions. Thus, a phenomenon that current through the channel region is concentrated at edge portions of the drain region (which may occur in the conventional asymmetrical transistor) may be reduced and/or prevented.

The foregoing is illustrative of embodiments of the present invention and is not to be construed as limiting thereof. Although a few embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A semiconductor device comprising:
an active region of a semiconductor substrate, wherein the active region has a first conductivity type;
first and second impurity regions in the active region, wherein the first and second impurity regions have a second conductivity type opposite the first conductivity type, and wherein the first and second impurity regions are spaced apart to define a channel region therebetween;
a first source/drain region in the first impurity region, wherein the first source/drain region has the second conductivity type, and wherein an impurity concentration of the first source/drain region is greater than an impurity concentration of the first impurity region;
a second source/drain region in the second impurity region, wherein the second source/drain region has the second conductivity type, wherein an impurity concentration of the second source/drain region is greater than an impurity concentration of the second impurity region, and wherein the first and second source/drain region have about a same width in a direction perpendicular with respect to a direction between the first and second source/drain regions; and
a control gate on the channel region.

2. A semiconductor device according to claim 1 further comprising:
an insulating field layer on a surface of the semiconductor substrate, wherein portions of the insulating layer extend on portions of the first and second impurity regions.

3. A semiconductor device according to claim 2 wherein a first portion of the insulating field layer is on the second impurity region between the second source/drain region and the channel region.

4. A semiconductor device according to claim 3 wherein portions of the first impurity region between the first source/drain region and the channel region are free of the insulating field layer.

5. A semiconductor device according to claim 4 wherein a second portion of the insulating field layer is on the second impurity region so that the second source/drain region is between the first and second portions of the insulating field layer, and wherein a third portion of the insulating field layer is on the first impurity region so that the first source/drain region is between the channel region and the third portion of the insulating field layer.

6. A semiconductor device according to claim 3 wherein the control gate includes a gate insulation layer on the channel region and a gate conductive layer on the gate insulation layer wherein portions of the gate conductive layer extend onto the first portion of the insulating field layer.

7. A semiconductor device according to claim 6 wherein a thickness of the insulating field layer is greater than a thickness of the gate insulation layer.

8. A semiconductor device according to claim 1 wherein current flow between the first and second source/drain regions is through the channel region in a direction perpendicular with respect to a direction of the widths of the first and second source/drain regions.

9. A semiconductor device according to claim 1 wherein the first and second source/drain regions are spaced from edge portions of the first and second impurity regions by a distance of at least about 2.5 Angstroms.

10. A semiconductor device according to claim 1 wherein the first and second source/drain regions are spaced from edge portions of the first and second impurity regions by a distance of at least about 2.5 Angstroms in the direction perpendicular with respect to the direction between the first and second source/drain regions.

11. A semiconductor device according to claim 1 wherein the control gate includes a gate insulation layer on the channel region and a gate conductive layer on the gate insulation layer wherein portions of the gate insulation layer extend beyond the gate conductive layer onto portions of the first impurity regions so that portions of the gate insulation layer are free of the gate conductive layer.

12. A semiconductor device according to claim 1 wherein the control gate includes a gate insulation layer on the channel region and a gate conductive layer on the gate insulation layer wherein a width of the gate insulation layer in the direction perpendicular with respect to the direction between the first and second source/drain regions is greater than a width of the gate conductive layer in the same direction.

13. A semiconductor device according to claim 1 wherein the first source/drain region comprises a source and wherein the second source/drain region comprises a drain.

14. A semiconductor device according to claim 1 wherein a distance between the first source/drain region and the channel region is less than a distance between the second source/drain region and the channel region.

15. A method of forming a semiconductor device, the method comprising:
forming first and second impurity regions in an active region of a semiconductor substrate, wherein the active region has a first conductivity type, wherein the first and second impurity regions have a second conductivity type opposite the first conductivity type, and wherein the first and second impurity regions are spaced apart to define a channel region therebetween;
forming a control gate on the channel region;
forming a first source/drain region in the first impurity region, wherein the first source/drain region has the second conductivity type, and wherein an impurity concentration of the first source/drain region is greater than an impurity concentration of the first impurity region; and
forming a second source/drain region in the second impurity region, wherein the second source/drain region has the second conductivity type, wherein an impurity concentration of the second source/drain region is greater than an impurity concentration of the second impurity region, and wherein the first and second source/drain region have about a same width in a direction perpendicular with respect to a direction between the first and second source/drain regions.

16. A method according to claim 15 further comprising:
before forming the control gate, forming an insulating field layer on a surface of the semiconductor substrate, wherein portions of the insulating layer extend on portions of the first and second impurity regions.

17. A method according to claim 16 wherein forming the insulating field layer comprises forming the insulating field layer using local oxidation of silicon (LOCOS).

18. A method according to claim 16 wherein a first portion of the insulating field layer is on the second impurity region between the second source/drain region and the channel region.

19. A method according to claim 18 wherein portions of the first impurity region between the first source/drain region and the channel region are free of the insulating field layer.

20. A method according to claim 19 wherein a second portion of the insulating field layer is on the second impurity region so that the second source/drain region is between the first and second portions of the insulating field layer, and wherein a third portion of the insulating field layer is on the first impurity region so that the first source/drain region is between the channel region and the third portion of the insulating field layer.

21. A method according to claim 20 wherein forming the first and second source/drain regions comprises implanting impurities for the first and second source/drain regions using the first, second, and third portions of the insulating field layer and the control gate as an implant mask.

22. A method according to claim 18 wherein forming the control gate includes,
forming a gate insulation layer on the channel region, and
forming a gate conductive layer on the gate insulation layer wherein portions of the gate conductive layer extend onto the first portion of the insulating field layer.

23. A method according to claim 22 wherein a thickness of the insulating field layer is greater than a thickness of the gate insulation layer.

24. A method according to claim 15 wherein current flow between the first and second source/drain regions is through the channel region in a direction perpendicular with respect to a direction of the widths of the first and second source/drain regions.

25. A method according to claim 15 wherein the first and second source/drain regions are spaced from edge portions of the first and second impurity regions by a distance of at least about 2.5 Angstroms.

26. A method according to claim 15 wherein the first and second source/drain regions are spaced from edge portions of the first and second impurity regions by a distance of at least about 2.5 Angstroms in the direction perpendicular with respect to the direction between the first and second source/drain regions.

27. A method according to claim 15 wherein forming the control gate includes,
forming a gate insulation layer on the channel region, and
forming a gate conductive layer on the gate insulation layer wherein portions of the gate insulation layer extend beyond the gate conductive layer onto portions of the first impurity regions so that portions of the gate insulation layer are free of the gate conductive layer.

28. A method according to claim 15 wherein forming the control gate includes,
forming a gate insulation layer on the channel region, and
forming a gate conductive layer on the gate insulation layer wherein a width of the gate insulation layer in the direction perpendicular with respect to the direction between the first and second source/drain regions is greater than a width of the gate conductive layer in the same direction.

29. A method according to claim 15 wherein the first source/drain region comprises a source and wherein the second source/drain region comprises a drain.

30. A method according to claim 15 wherein a distance between the first source/drain region and the channel region is less than a distance between the second source/drain region and the channel region.
